(19) United States
(12) Patent Application Publication
(10) Pub. No.: US 2007/0034601 A1
(43) Pub. Date: Feb. 15, 2007

(54) Surface treating method and surface-treating apparatus

(75) Inventors: Toshio Goto, Aichi (JP); Masaru Hori, Aichi (JP); Nobuo Ishii, Hyogo (JP); Shoji Den, Kanagawa (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/550,020

(22) PCT Filed: Sep. 22, 2003
(86) PCT No.: PCT/JP03/12105

§ 371 Date: Sep. 20, 2006

(30) Foreign Application Priority Data
Mar. 24, 2003 (JP) 2003081556

(51) Int. Cl. C03C 15/00; H01L 21/302; B44C 1/22

(52) U.S. Cl. 216/57; 156/345.12; 216/62; 438/704

(57) ABSTRACT

The surface of a material for an electronic device is flattened by irradiating the surface of the material with at least part of plasma components, while supplying a liquid to the surface of the material for an electronic device. There are provided a method of treating the surfaces for favorably flattening the surface of the material for an electronic device or of the substrate for an electronic device, while suppressing damage to the material or to the substrate, and an apparatus for treating the surfaces.

### TECHNICAL FIELD

The present invention relates to a surface-treating apparatus capable of favorably flattening the surface of a material for an electronic device or of a substrate for an electronic device that is to be flattened, while suppressing the damage to the material or substrate.

### BACKGROUND ART

The present invention can be widely applied to the production of the materials for electronic devices, such as semiconductors or semiconductor devices, and liquid crystal devices. Here, for convenience of explanation, there will be exemplified the background art relating to the semiconductor devices.

The semiconductor as represented by silicon and the substrate for electronic device materials are subjected to various treatments such as forming an insulating film like an oxide film, depositing a film by CVD and etching.

It is not too much to say that performance of modern semiconductor devices has developed being supported by the technology for fabricating fine devices as represented by transistors. Continuing efforts have been made to improve the technology for fabricating fine semiconductor devices for further enhancing performance. To meet the requirements for finely fabricating the semiconductor devices and for enhancing the performance in recent years, an increasing importance has been placed on the technology for flattening the substrates or various treated articles (e.g., interlayer insulating film on the substrate or in the substrate, and metal wiring of a buried pattern).

This is because, in forming, for example, a semiconductor device in a multiplicity of layers, if the substrate or the article being subjected to the intermediate treatment is rugged on the surfaces thereof, it becomes difficult to form another layer or wiring thereon.

A so-called CMP (chemical mechanical polishing) process has so far been mainly used for flattening the surfaces of the substrate in the production of semiconductor devices or of various treated articles, since it is capable of easily flattening the surfaces that are to be formed.

Accompanying a rapid development such as forming a substrate (wafer) of a large diameter for semiconductors, finely forming the patterns and forming a multiplicity of layers, the CMP process is now becoming a technology indispensable for a modern process for producing VLSI's.

In the CMP apparatus used for the CMP process, the surface of the wafer is polished by pushing the surface of the wafer that is rotating onto a polishing cloth (pad) on a disk that is rotating while supplying a slurry (fluid containing a polishing material) by dripping onto the pad. In polishing, for example, silicon or oxide film, there is used silica or zirconia (ZrO₂) as a polishing material and in polishing a metal used for the wiring, there is used, in many cases, alumina or manganese dioxide as a polishing material, though the polishing material used for the CMP may differ depending upon the object to be polished.

In conducting the polishing relying upon the above-mentioned CMP process which effects the mechanical/chemical polishing, however, it was difficult to avoid the occurrence of damage such as “scratches” on the surfaces of the wafer due to mutual action between the polishing agent and the surfaces of the wafer.

### DISCLOSURE OF THE INVENTION

An object of the present invention to provide a surface treating method and a surface-treating apparatus free of the above-mentioned problem encountered in the prior art.

Another object of the present invention is to provide a surface treating method and a surface-treating apparatus capable of favorably flatting the surfaces of a material for an electronic device or of a substrate for an electronic device, while suppressing the damage to such material or substrate.

As a result of earnest study, the present inventors have found that, it is very effective in achieving the above object, to polish the material for an electronic device or the substrate for an electronic device by a combination of chemical/chemical actions or chemical/electric actions based on a combination of a plasma (or, one or more kinds of those selected from radicals, positive ions and negative ions based on a plasma) and a liquid (i.e., in a wet state), instead of polishing the material for the electronic device or the substrate for the electronic device simply on the basis of combination of mechanical/chemical actions in the prior art.

A surface-treating method according to the present invention is based on the above discovery. More specifically, the surface-treating method comprises irradiating the surface of the material with at least a part of plasma components, while supplying a liquid to the surface of the material, to thereby flatten the surface of the material.

The present invention also provides a surface-treating apparatus, comprising at least: a processing chamber for placing a material for an electronic device to be treated at a predetermined position therein; material-holding means for holding the material for an electronic device in the processing chamber (the holding means can include a heater for heating the substrate and an electrostatic chuck for intimately attaching the substrate to the holding means); liquid-supplying means for supplying a liquid onto the surface of the material for an electronic device; and plasma-processing means for treating the surface of the material for an electronic device with a plasma; whereby the surface of the material can be irradiated with the plasma, while supplying the liquid onto the surface of the material for an electronic device.

### BRIEF DESCRIPTION OF THE DRAWINGS

FIG. 1 is a schematic perspective view showing an embodiment of the surface-treating apparatus according to the present invention.

FIG. 2 is a schematic perspective view showing an embodiment of the conventional CMP apparatus.

FIG. 3 is a schematic perspective view showing another embodiment of the conventional CMP apparatus.

FIG. 4 is a schematic perspective view showing another embodiment of the surface-treating apparatus according to the present invention.

FIG. 5 is a schematic sectional view for illustrating the effect of the surface-treating apparatus according to the present invention.

FIG. 6 is a schematic sectional view showing a further embodiment of the surface-treating apparatus according to the present invention;

FIG. 7 is a graph showing an example of the high-speed oxide film (SiO₂) etching characteristic that can be obtained by the present invention.

FIG. 8 is a graph, etc., showing an example of the presumed etching mechanism that can be obtained by the present invention.

FIG. 9 is a photograph showing the results of anisotropic etching that can be obtained by the present invention.

### BEST MODE FOR CARRYING OUT THE INVENTION

The present invention will be described more specifically with reference to the drawings, as desired. In the following description, “parts” and “%” representing the ratios of amounts are on the basis of mass unless stated otherwise.

(Surface-Treating Method)

In the surface-treating method according to the present invention, the surface of a material for an electronic device is flattened by irradiating the surface of the material with a plasma, while supplying a liquid onto the surface of the material. The “material for an electronic device” may be a substrate itself for an electronic device that will be described later, or may be a treated article which has been obtained by subjecting such a substrate to any of various treatments (e.g., treated intermediate article or product having an interlayer insulating film, a gate-insulating film, or buried-type or embedded-type metal wiring (such as damascene) which has been formed on the substrate or in the substrate for an electronic device.

(Substrate for an Electronic Device)

There is no particular limitation on the substrate for an electronic device that can be used in the present invention. It is possible to use one or combination of two or more kinds which are appropriately selected from known materials for electronic devices. As such substrates for electronic devices, there can be used a semiconductor material and a liquid crystal device material. As the semiconductor material, there can be exemplified a material comprising mainly single crystalline silicon, a material comprising mainly GaAs and a material obtained by depositing a film of a metal on a semiconductor substrate.

(Liquid)

There is no particular limitation on the liquid that is supplied onto the surfaces of the material for an electronic device so far as it works advantageously (e.g., promoting the polishing, lowering damage to the surfaces of the material) based on a combination with a plasma (or radicals, positive ions or negative ions based on the plasma) used in the present invention. Examples of the liquid that can be favorably used in the present invention are as described below. This “liquid” may be a single substance or a mixture (e.g., solution).
(1) Alkaline liquid.
   Organic alkaline solution, NH₄, KOH
(2) Acidic liquid.
   HCl, HF, H₂SO₄, HCl+H₂O₂, H₂SO₄+H₂O₂
(3) Neutral liquid.
   H₂O
      (Plasma)

There is no particular limitation on the plasma that is supplied onto the surfaces of the material for an electronic device so far as it works advantageously (e.g., promoting the polishing, lowering damage to the surfaces of the material) based on a combination with the above-mentioned liquid used in the present invention. Examples of the plasma that can be favorably used in the present invention are as described below.
(1) Principle of Generating a Plasma.

There is no particular limitation. Namely, there can be used any one of a parallel flat plate-type plasma, an induction coupled-type (ICP) plasma or a microwave supply-type plasma.
(2) Pressure when Generating a Plasma.

There is no particular limitation. Namely, it may be either a reduced pressure plasma or an atmospheric pressure plasma. It is desired to use a non-equilibrium atmospheric pressure plasma from the standpoint of a high concentration of the plasma specifies that can be used for treating the surfaces. The pressure, however, may be greater than the atmospheric pressure.
(3) Plasma Component to be Supplied.

The above plasma may be a plasma itself (i.e., whole components constituting the plasma) or may be the one in which, as desired, the radicals, positive ions and negative ions based on the plasma are selected or their ratio of constitution is suitably varied, and is supplied onto the surface of the material for an electronic device.

(Rare Gases)

There is no particular limitation on the rare gases that can be used in the present invention. There can be suitably selected any known rare gases that are used for the production of electronic devices, and can be used in one kind or in two or more kinds in combination.

Examples of the treating gas include krypton (Kr), xenon (Xe), helium (He) and argon (Ar).

(Etching Gas)

In the present invention, it is desired to use an etching gas for generating a plasma from the standpoint of favorably accomplishing the flattening. There is no particular limitation on the etching gas that can be used, and there can be suitably selected any known etching gas (e.g., fluorine-contained gas) that are used for the production of electronic devices, and can be used in one kind or in two or more kinds in combination.

Examples of the treating gas include the following, i.e., CF₄, C₂F₆, C₃F₈, C₄F₈, CHF₃, CH₂F₂, CCl₄, CHCl₃, HCl, C₅F₇, Cl₂, BCl₃, HF, F₂, H₂, O₂, HBr, Br, I₂, HI and NF₃.

(Treating Conditions)

The surface treatment of the present invention favorably employs the following conditions from the standpoint of flattening that is accomplished.
(1) Rare gas (e.g., He): He, not smaller than about 16 L/min.
(2) NF₃: up to 30 sccm, trace amount of H₂O, about 2 sccm of C₄F₈
(3) Temperature: −50° C. to 400° C., more preferably, 10° C. to 200° C.
(4) Pressure: 10 mtorr to 1520 torr, preferably, about 760 torr
(5) Microwaves: 200 to 1000 W
   (Preferred Plasma)

Characteristics of a plasma that can be favorably used in the present invention are as follows:
(1) Electron temperature: 0.5 to 5 ev
(2) Density: 10¹¹ to 10¹⁶ [cm⁻³]
   (Plane Antenna Member)

In the surface-treating method according to the present invention, the surfaces are irradiated with microwaves via a plane antenna member having a plurality of slots to form a highly dense plasma having a low electron temperature. According to the present invention which effects the flattening by using a plasma having such excellent characteristics, it is made possible to carry out a highly reactive process at a low temperature. According to the present invention which irradiates microwaves via the plane antenna member, further, there is obtained an advantage in that the flattening is easily accomplished as desired even under a high pressure (e.g., under an atmospheric pressure)(as compared to when a conventional plasma is used).

(An Embodiment of a Surface-Treating Apparatus)

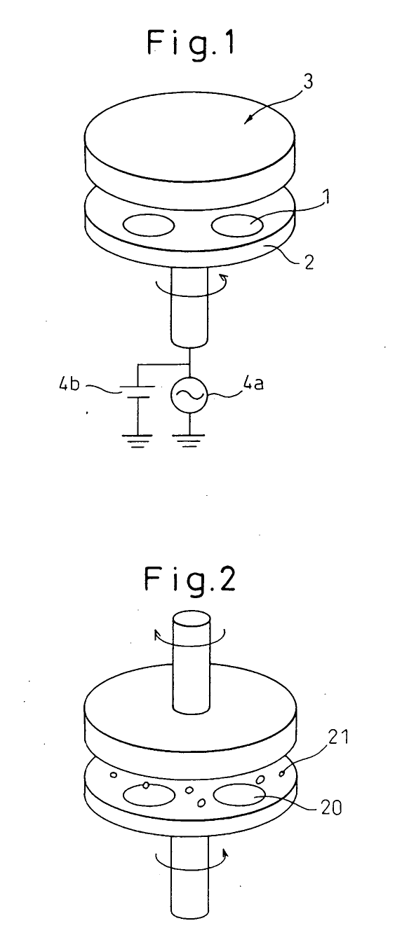

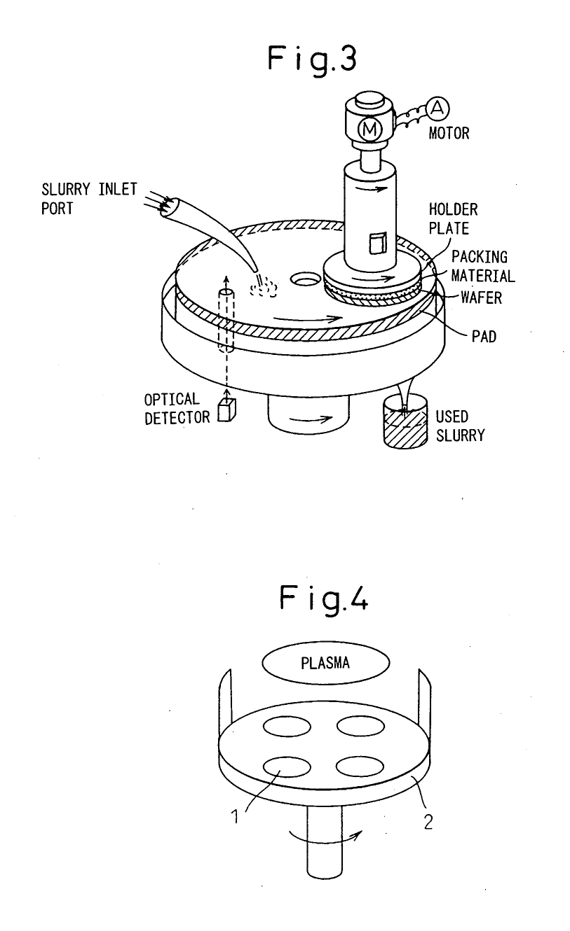

Described below is a preferred embodiment of the surface-treating apparatus according to the present invention. FIG. 1 is a schematic perspective view showing the surface-treating apparatus of the embodiment. For comparison, FIGS. 2 and 3 are perspective views schematically illustrating conventional CMP apparatuses.

Referring to FIG. 1, in a processing chamber that is not shown, there are arranged a material-holding means 2 for driving (rotating) the material for an electronic device, and a liquid-supplying means (not shown) for supplying a liquid onto the surface of the material 1 for the electronic device. Plasma-processing means 3 is arranged at a position facing the surface of the material 1 for an electronic device in the processing chamber in order to irradiate the surface of the material 1 for an electronic device with at least part of the plasma components. In this embodiment constituted as described above, the surface of the material 1 is flattened by irradiating the surface of the material 1 with at least part of the plasma components based on the plasma-processing means 3 while supplying a liquid from the liquid-supplying means onto the surface of the material 1 for an electronic device, while suppressing damage to the surface of the material 1.

(Utilizing the Bias)

In the constitution shown in FIG. 1, a desired DC and/or AC bias can be applied to the member 1 held by the material-holding means 2 from bias-applying means 4a and 4b connected to the material-holding means 2. By applying a bias to the material 1 as described above, the surface of the material 1 can be easily flattened by utilizing the energy of positive or negative ions stemming from the plasma.

(Conventional CMP Apparatus)

In the conventional CMP apparatuses shown in FIGS. 2 and 3, on the other hand, the surface of the wafer 20 tended to be easily damaged due to mechanical contact between the wafer 20 and a hard polishing material (e.g., silica SiO₂ particles) included in the agent slurry (not shown) supplied onto the surface of the wafer 20 from a nozzle (not shown).

### Other Embodiment 1

FIG. 4 illustrates another embodiment of the surface-treating apparatus according to the present invention. This embodiment is the same as the embodiment of FIG. 1 except that “vane”-like members are attached in a plural number to the material-holding means 2. In the embodiment of FIG. 4, for example, when the etching gas is used, a “whirlwind” of gas flows on the electronic device material 1 (flow of the reacted gas is quickly discharged to the outer side from the region of treating the substrate), whereby the gas flows more smoothly and the electronic device material 1 is easily flattened more uniformly.

(Effect for Flattening)

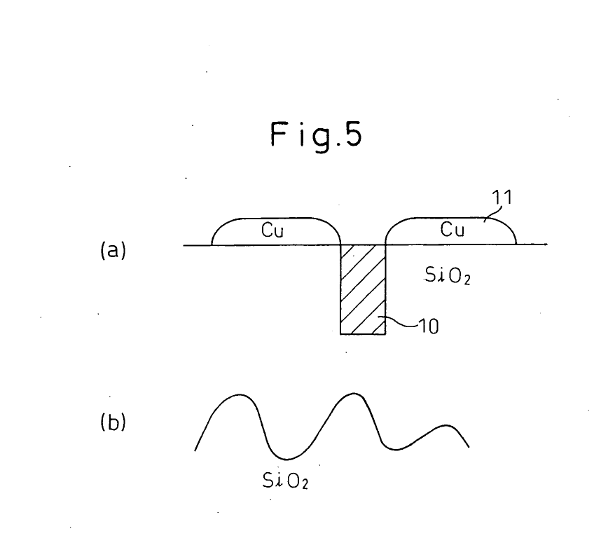

According to the present invention, portions 11 protruding beyond the surface of the SiO₂ material can be favorably flattened (without substantially damaging other portions) in forming a buried-type copper wiring 10 in the SiO₂ material as shown in FIG. 5(a).

Moreover, ruggedness of the surface itself of the SiO₂ material as shown in FIG. 5(b) can be easily flattened.

### Other Embodiment 2

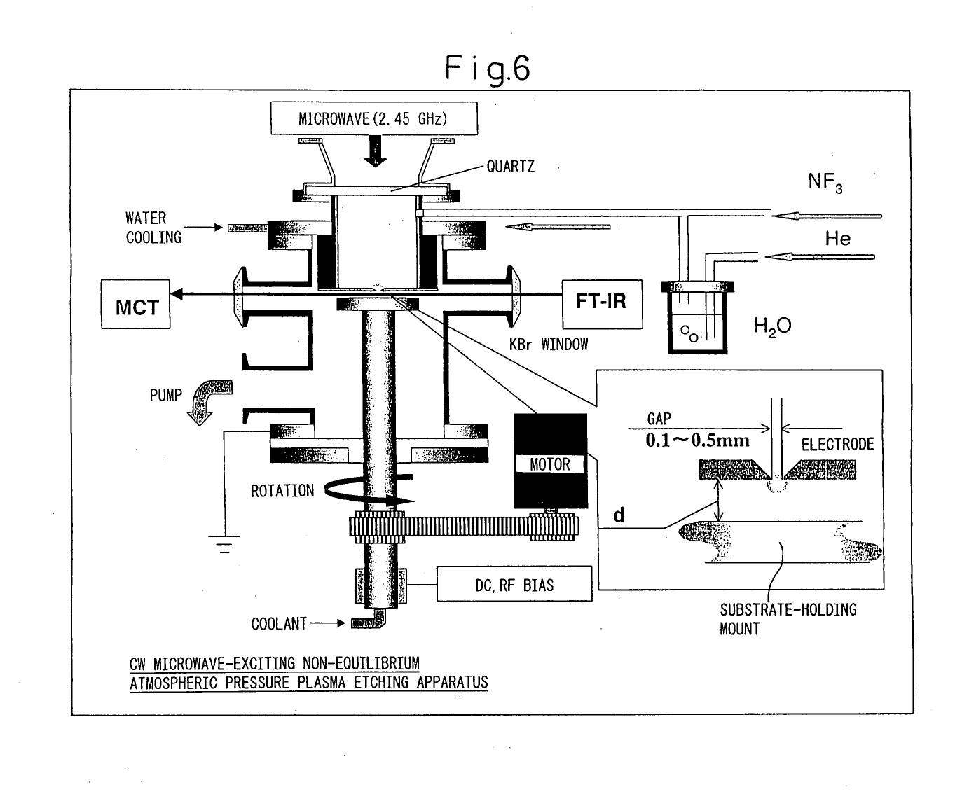

FIG. 6 illustrates a further embodiment of the surface-treating apparatus according to the present invention. This embodiment uses NF₃ as the etching gas and H₂O as the liquid. H₂O is obtained by bubbling a He gas. This is not limited to the bubbling means only but may be a carburetor, or may be to directly inject the liquid. An oxide film (SiO₂) has been deposited on the substrate, and is efficiently etched.

(Effect of Etching)

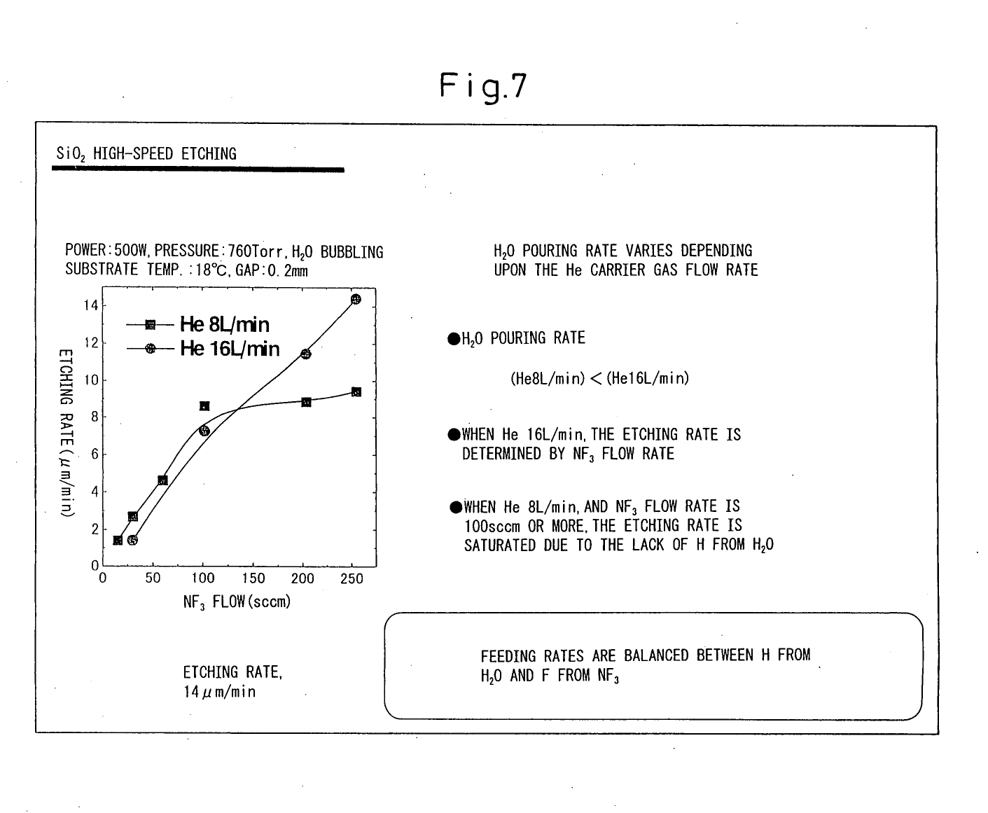

The above embodiment makes it possible to etch the oxide film (SiO₂) at a high speed (FIG. 7).

At the same time, there is confirmed a favorable selection ratio for the resist and the Si substrate which are the organic materials.

(Etching Mechanism)

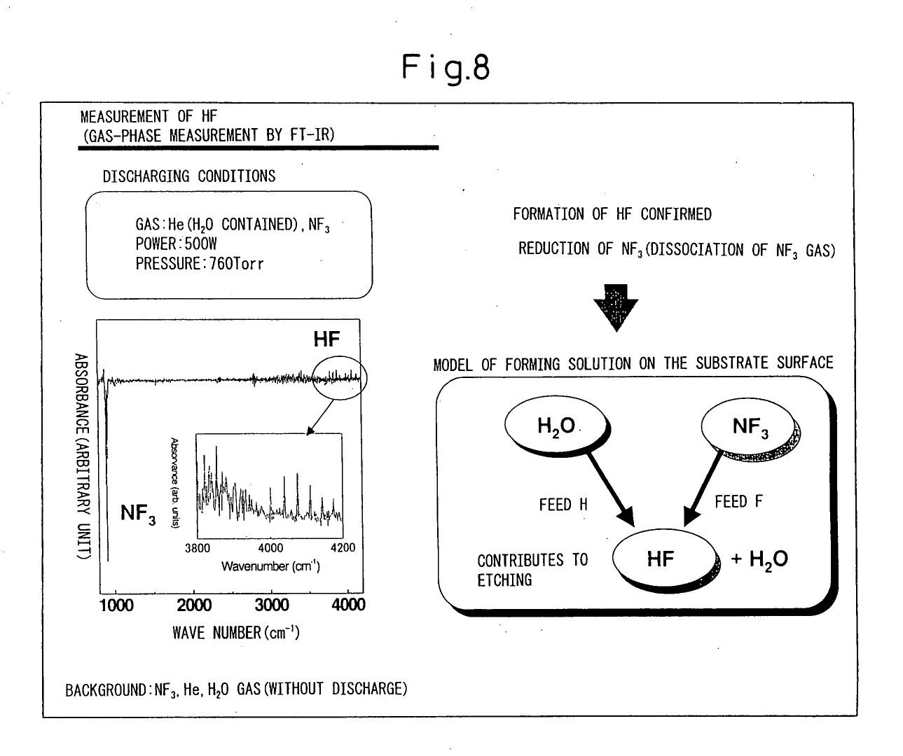

The above high-speed etching characteristics are obtained as the NF₃ gas that is introduced reacts with H₂O on the surface of the material to be treated to generate HF which promotes the etching (FIG. 8).

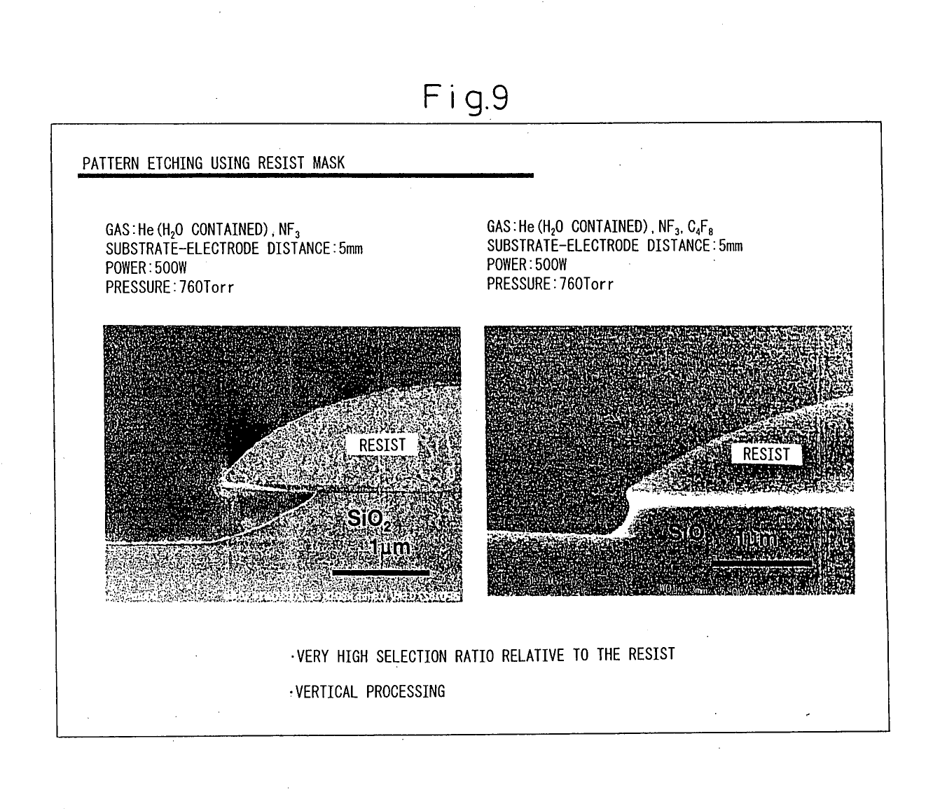

When a CFₓ-type gas, e.g., a C₄F₈ gas is added in small amounts to the treating gas, the anisotropy of etching is confirmed, too (FIG. 9).

(Other Application)

The above embodiments can be effectively applied not only to the SiO₂ film but also to etching and flattening the oxides containing Zr and Hf having high dielectric constants.

### INDUSTRIAL APPLICABILITY

As described above, the present invention makes it possible to favorably flatten the surface of a material for an electronic device or of a substrate for an electronic device, while suppressing damage to the material or to the substrate.

1. A method of treating:the surface of a material for an electronic device, comprising irradiating the surface of the material with at least a part of plasma components, while supplying a liquid to the surface of the material, to thereby flatten the surface of the material.

2. A method of treating the surface of a material for an electronic device according to claim 1, wherein the material for an electronic device is a substrate for an electronic device.

3. A method of treating the surface of a material for an electronic device according to claim 1, wherein radicals, positive ions or negative ions based on a plasma are selectively supplied onto the surface of the material for an electronic device.

4. A method of treating the surface according to claim 1, wherein the liquid is H₂O.

5. A method of treating the surface according to claim 3, wherein the radicals are high-speed neutral radicals.

6. A surface-treating apparatus, comprising at least:
a processing chamber for placing a material for an electronic device to be treated at a predetermined position therein;
material-holding means for holding the material for an electronic device in the processing chamber;
liquid-supplying means for supplying a liquid onto the surface of the material for an electronic device; and
plasma-processing means for treating the surface of the material for an electronic device with a plasma;
whereby the surface of the material can be irradiated with the plasma, while supplying the liquid onto the surface of the material for an electronic device.

7. A surface-treating apparatus according to claim 6, comprising particle selection means for selectively irradiating the surface of the material for an electronic device with at least one kind of those selected from radicals, positive ions and negative ions of the plasma components to be supplied from the plasma-processing means.
